(19) United States
(12) Patent Application Publication
(10) Pub. No.: US 2025/0286353 A1
(43) Pub. Date: Sep. 11, 2025

(54) WATERPROOF HEAT DISSIPATION CABINET

(71) Applicant: Fortune Electric Co., Ltd., Taoyuan City (TW)

(72) Inventors: Chia-Ching LIN, Taoyuan City (TW); Ching-Min CHEN, Taoyuan City (TW); Chia-Tai HSU, Taoyuan City (TW)

(21) Appl. No.: 18/976,476

(22) Filed: Dec. 11, 2024

(30) Foreign Application Priority Data
Mar. 6, 2024 (TW) 113108042

(51) Int. Cl. H02B 1/56; H02B 1/30; H05K 5/02; H05K 7/20

(52) U.S. Cl. CPC H02B 1/565; H02B 1/30; H05K 5/0214; H05K 7/20336; H05K 7/2039

(57) ABSTRACT

A waterproof heat dissipation cabinet includes an inner cabinet body and an outer cover housing the inner cabinet body. The inner cabinet body includes a bottom wall, a top wall, a rear wall, and two side walls that jointly define an accommodation space, and the bottom wall has a plurality of first ventilation holes. The outer cover includes a top baffle, a rear baffle, and two side baffles. The top baffle corresponds in position to the top wall. The rear baffle corresponds in position to the rear wall, and has a plurality of heat dissipation holes that provide for air communication between at least one heat dissipation window of the rear wall and the external environment. The two side baffles respectively correspond in position to the two side walls, and each of the two side baffles shelters a plurality of second ventilation holes of the corresponding side wall.

### CROSS-REFERENCE TO RELATED PATENT APPLICATION

This application claims the benefit of priority to Taiwan Patent Application No. 113108042, filed on Mar. 6, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a cabinet for electronic devices, and more particularly to a waterproof heat dissipation cabinet, which is adapted to a voltage regulating device being placed outdoors for a long period of time.

### BACKGROUND OF THE DISCLOSURE

With the promotion of grid construction, more and more electronic cabinets are used in power transmission and distribution systems, so as to protect electronic devices placed outdoors from environmental factors, such as communication devices, monitoring devices, and voltage regulating devices.

An electronic cabinet installed outdoors will inevitably be infiltrated by water, causing electronic devices in the cabinet to fail to operate normally. For example, in heavy rain, rainwater can enter the electronic cabinet from the top or sides of the cabinet. Therefore, the structural design of electronic cabinets requires waterproofing. In addition, not only are these electronic cabinets often directly exposed to strong sunlight, but the electronic devices within the cabinet will also generate heat, so that the temperature in the cabinet will increase. When the temperature in the cabinet is too high, the electronic devices will risk decreasing in service life or even be damaged.

However, striking a balance between waterproof functions and heat dissipation effects has always been a challenge in the related art. If a heat dissipation problem is solved, it would be difficult to achieve a good waterproof effect, and vice versa. Therefore, outdoor cabinets need to be improved in structure to increase resistance to rainwater and enhance heat dissipation and cooling performances, so as to overcome the above-referenced technical inadequacies.

### SUMMARY OF THE DISCLOSURE

In response to the above-referenced technical inadequacies, the present disclosure provides a waterproof heat dissipation cabinet with good waterproof and heat dissipation capabilities, which can improve the reliability and service life of electronic components stored therein.

In order to solve the above-mentioned problems, one of the technical aspects adopted by the present disclosure is to provide a waterproof heat dissipation cabinet, which includes an inner cabinet body and an outer cover. The inner cabinet body is housed in the outer cover. The inner cabinet body includes a bottom wall, a top wall, a rear wall, and two side walls that jointly define an accommodation space. The bottom wall has a plurality of first ventilation holes. The rear wall has at least one heat dissipation window. Each of the two side walls has a plurality of second ventilation holes. The outer cover includes a top baffle, a rear baffle, and two side baffles. The top baffle corresponds in position to the top wall. The rear baffle corresponds in position to the rear wall. The two side baffles respectively correspond in position to the two side walls, and each of the two side baffles shields the second ventilation holes of the corresponding side wall. Furthermore, the rear baffle has a plurality of heat dissipation holes that provide for air communication between the at least one heat dissipation window and the external environment.

In conclusion, by virtue of the inner cabinet body including a bottom wall having a plurality of first ventilation holes, a rear wall having at least one heat dissipation window, and two side walls each having a plurality of second ventilation holes, and the outer cover including two side baffles each blocking a plurality of second ventilation holes of the corresponding side wall and a rear baffle having a plurality of heat dissipation holes that provide for air communication between the at least one heat dissipation window of the rear wall and the external environment, the waterproof heat dissipation cabinet provided by the present disclosure can not only achieve a high waterproof grade that is ideal for long-term outdoor use, but also meet the heat dissipation requirements of high-power electronic components.

More specifically, the waterproof heat dissipation cabinet provided by the present disclosure can fully utilize natural air for heat dissipation and prevent rainwater from entering the inner cabinet body through hollow structures (e.g., holes, openings, or gaps), thereby being highly practical in the field of outdoor cabinets. After testing, the waterproof heat dissipation cabinet provided by the present disclosure can reach the waterproof grade of IPX6.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective exploded view of a waterproof heat dissipation cabinet according to a first embodiment of the present disclosure;

FIG. 2 is a schematic perspective assembled view of the waterproof heat dissipation cabinet according to the first embodiment of the present disclosure;

FIG. 3 is another schematic perspective assembled view of the waterproof heat dissipation cabinet according to the first embodiment of the present disclosure;

FIG. 4 is a schematic perspective view of an inner cabinet body of the waterproof heat dissipation cabinet according to the first embodiment of the present disclosure;

FIG. 5 is another schematic perspective view of the inner cabinet body of the waterproof heat dissipation cabinet according to the first embodiment of the present disclosure;

FIG. 6 is a schematic perspective view of an outer cover of the waterproof heat dissipation cabinet according to the first embodiment of the present disclosure;

FIG. 7 is a schematic enlarged view of the inner cabinet body of the waterproof heat dissipation cabinet according to the first embodiment of the present disclosure;

FIG. 8 is a schematic perspective exploded view of a waterproof heat dissipation cabinet according to a second embodiment of the present disclosure;

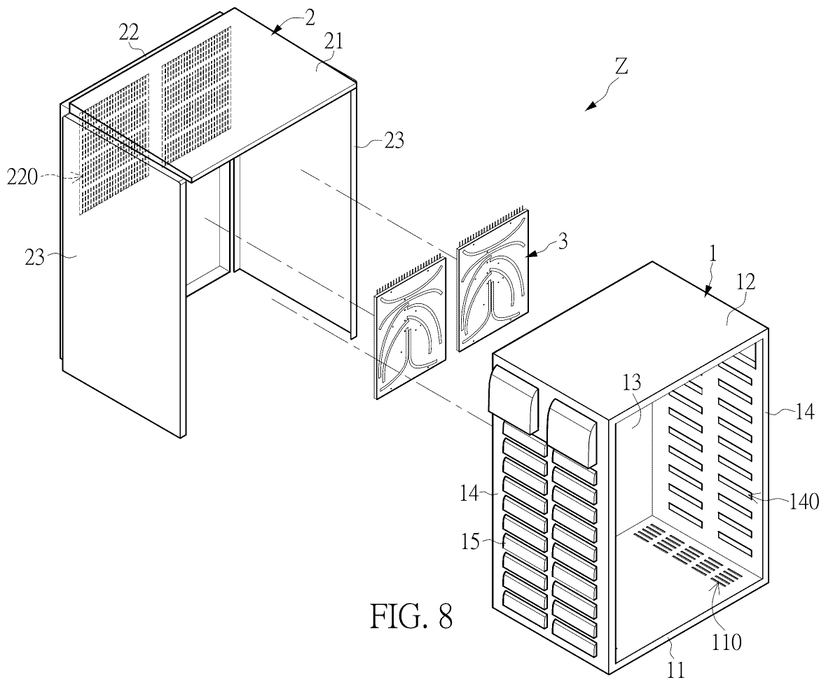

FIG. 9 is a schematic perspective assembled view of the waterproof heat dissipation cabinet according to the second embodiment of the present disclosure;

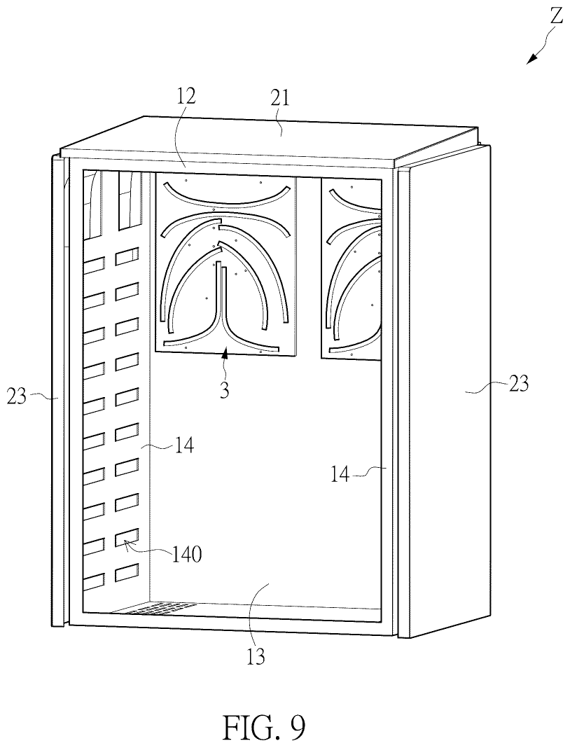

FIG. 10 is a schematic perspective view of a heat sink of the waterproof heat dissipation cabinet according to the second embodiment of the present disclosure; and

FIG. 11 is a schematic view showing a use state of the waterproof heat dissipation cabinet according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

Striking a balance between waterproof functions and heat dissipation effects has always been a challenge in the related art. If a heat dissipation problem is solved, it would be difficult to achieve a good waterproof effect, and vice versa. Therefore, the present disclosure provides a waterproof heat dissipation cabinet that adopts a double-layered design for inner and outer structures in combination with specific configurations of waterproof and heat dissipation mechanisms can achieve an effective balance between waterproof and heat dissipation capabilities.

### First Embodiment

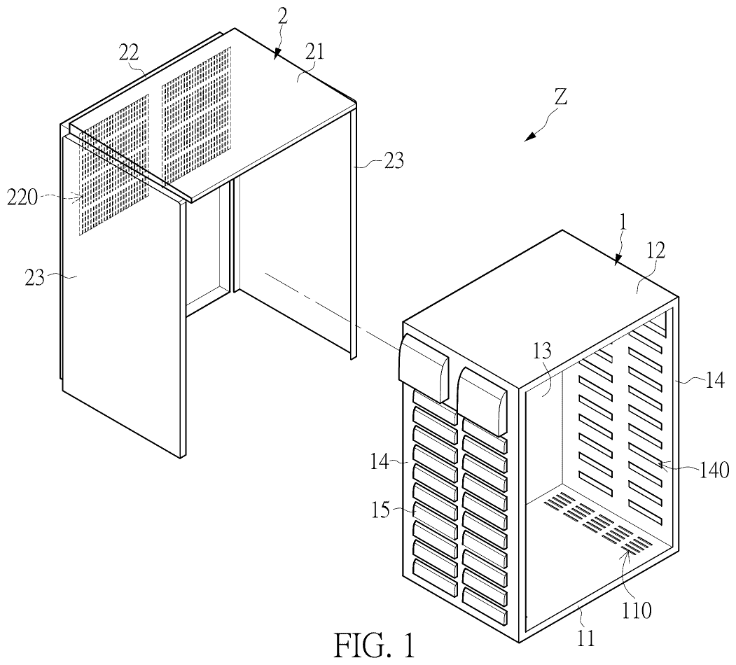

Referring to FIG. 1 to FIG. 3, the structure of a waterproof heat dissipation cabinet Z according to a first embodiment of the present disclosure is shown. As shown in FIG. 1 to FIG. 3, the waterproof heat dissipation cabinet Z includes an inner cabinet body 1 and an outer cover 2, and the inner cabinet body 1 is housed in the outer cover 2, i.e., the inner cabinet body 1 is disposed on the inside of the outer cover 2. In use, one or more components and devices, such as electronic components and devices required for voltage regulation of a transformer in a power system, can be disposed in an accommodation space 100 of the inner cabinet body 1 to have a double-layered protection against rain and solar radiation as provided by the inner cabinet body 1 and the outer cover 2. Furthermore, the inner cabinet body 1 can cooperate with the outer cover 2 to allow sufficient ventilation and air exchange in the accommodation space 100, so as to fully utilize natural air for heat dissipation. More technical details will be provided in the following paragraphs.

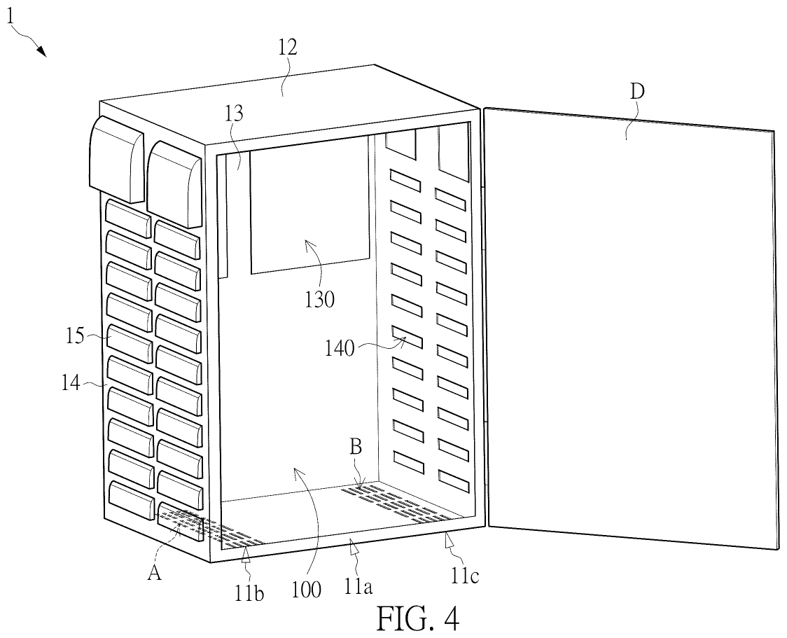

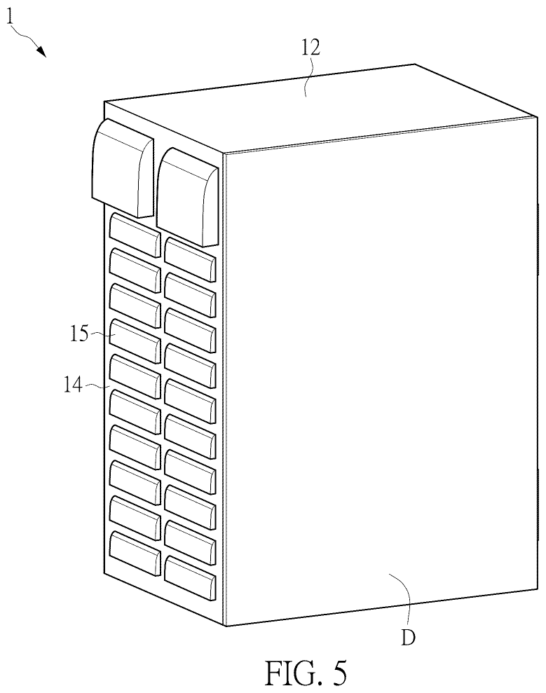

Reference is also made to FIG. 4 and FIG. 5. In the present disclosure, the inner cabinet body 1 includes a bottom wall 11, a top wall 12, a rear wall 13, and two side walls 14 that jointly define an accommodation space 100. The bottom wall 11 is opposite to the top wall 12, and the rear wall 13 is integrally connected between the bottom wall 11 and the top wall 12. The two side walls 14 are, for example, left and right side walls, and are opposite to each other and integrally connected between the bottom wall 11, the top wall 12, and the rear wall 13. The bottom wall 11 has a plurality of first ventilation holes 110. The rear wall 13 has at least one heat dissipation window 130. Each of the two side walls 14 has a plurality of second ventilation holes 140. The inner cabinet body 1 can be made of stainless steel, but is not limited thereto.

In the present embodiment, the bottom wall 11 of the inner cabinet body 1 has a central area 11a and first and second peripheral areas 11b, 11c located at two opposite sides of the central area 11a. The first ventilation holes 110 are arranged on the bottom wall 11 into two ventilation hole arrays A, B. One of the two ventilation hole arrays A, B is located in the first peripheral area 11b, and the other of the two ventilation hole arrays A, B is located in the second peripheral area 11c. Furthermore, the second ventilation holes 140 are arranged on each of the two side walls 14 of the inner cabinet body 1 in a pairwise side-by-side arrangement. However, the aforementioned description for the arrangement of the first ventilation holes 110 and the second ventilation holes 140 is only an example, and is not meant to limit the scope of the present disclosure.

In practice, the waterproof heat dissipation cabinet Z can include a cabinet door D that opens outwards. The cabinet door D is pivoted on the inner cabinet body 1, and can be flipped outwards relative to the inner cabinet body 1 to expose the accommodation space 100 or flipped inwards relative to the inner cabinet body 1 to close the accommodation space 100.

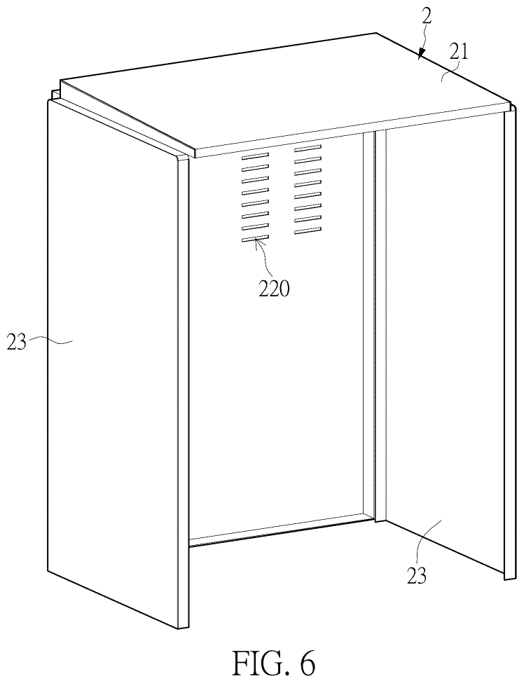

Reference is also made to FIG. 6. The outer cover 2 has a hollow section at the bottom thereof, which includes a top baffle 21, a rear baffle 22, and two side baffles 23. The top baffle 21 corresponds in position to the top wall 12 of the inner cabinet body 1. The rear baffle 22 corresponds in position to the rear wall 13 of the inner cabinet body 1. The two side baffles 23 respectively correspond in position to the two side walls 14 of the inner cabinet body 1. The outer cover 2 can be made of stainless steel, but is not limited thereto.

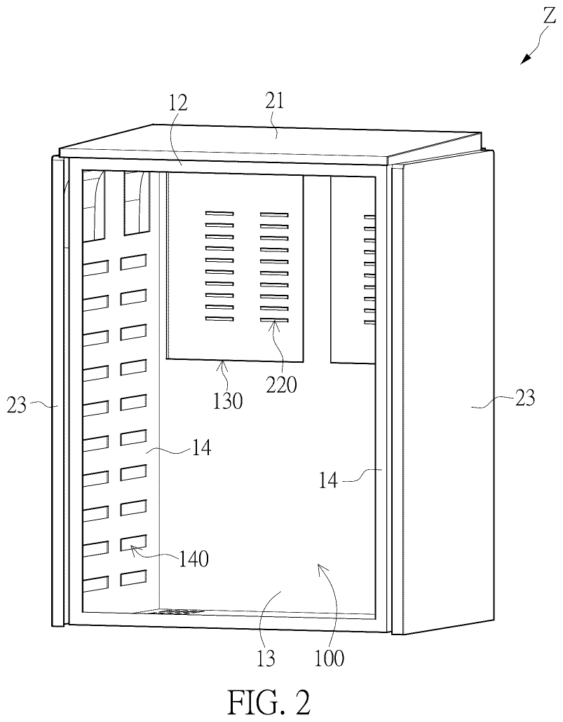

In the present embodiment, as shown in FIG. 2, the top wall 12 is completely within the cover range of the upper baffle 21, in which a ventilation space for air flow is present between the top wall 12 and the upper baffle 21. The rear wall 13 is completely within the cover range of the rear baffle 22, such that the at least one heat dissipation window 130 thereof is shielded by the rear baffle 22, in which a space for air flow is present between the rear wall 13 and the rear baffle 22 and in spatial communication with the external environment. Furthermore, the rear baffle 22 has a plurality of heat dissipation holes 220, and the at least one heat dissipation window 130 of the rear wall 13 is in air communication with the external environment through the heat dissipation holes 220. Preferably, the heat dissipation holes 220 are adjacent to the at least one heat dissipation window 13. Each of the two side walls 14 is completely within the cover range of the corresponding side baffle 23, such that the second ventilation holes 140 thereof are shielded by the corresponding side baffle 23, in which another space for air flow is present between each of the two side walls 14 and the corresponding side baffle 23 and in spatial communication with the external environment.

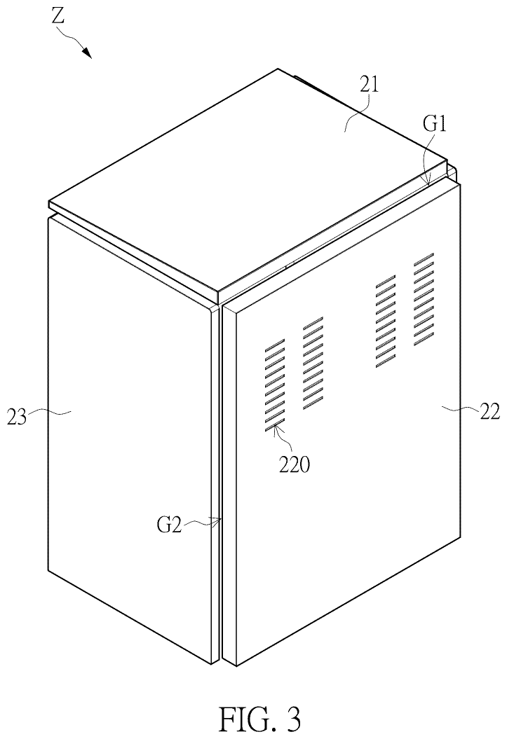

As shown in FIG. 3, the rear baffle 22 and each of the two side baffles 23 of the outer cover 2 have a heat dissipation gap G1 therebetween. The rear baffle 22 and top baffle 21 of the outer cover 2 have another heat dissipation gap G2 therebetween. Accordingly, at least one heat dissipation path can be shortened, thereby improving heat dissipation performance.

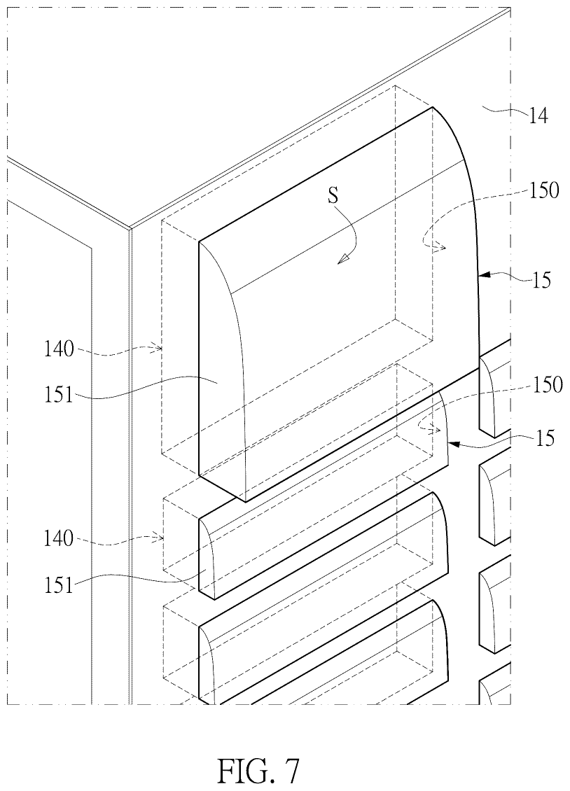

Referring to FIG. 2 and FIG. 3, which are to be read in conjunction with FIG. 7, at least one shielding portion 15 can be disposed between the inner cabinet body 1 and the outer cover 2 to shield the second ventilation holes 140 of the two side walls 14 of the inner cabinet body 1. Therefore, the probability of water entering the inner cabinet body 1 and causing damage to electronic components and devices can be greatly reduced. More specifically, each of the two side walls 14 and the corresponding side baffle 23 have a plurality of shielding portions 15 disposed therebetween to respectively shield the second ventilation holes 140, and each of the shielding portions 15 has an opening 150 that allows for air communication between the shielded second ventilation hole 140 and the external environment.

In practice, each of the shielding portions 15 has the function of guiding and draining rainwater, so as to avoid water accumulation between the two side walls 14 of the inner cabinet body 1 and the side baffle 23 of the outer cover 2. More specifically, each of the shielding portions 15 has a water shielding panel 151 that extends from an external wall surface of the corresponding side wall 14 to shield the corresponding second ventilation hole 140, and the water shielding panel 151 has a curved guiding surface S.

### Second Embodiment

Referring to FIG. 1 to FIG. 3, a second embodiment of the present disclosure provides a waterproof heat dissipation cabinet Z. In the present embodiment, in addition to the inner cabinet body 1 and the outer cover 2 as described in the first embodiment, the waterproof heat dissipation cabinet Z further includes at least one heat sink 3 that is disposed on a rear wall 13 of the inner cabinet body 1, thereby increasing heat dissipation performance for more stringent requirements in heat dissipation. Preferably, the at least one heat sink 3 passes through at least one heat dissipation window 130 of the rear wall 13 and serves as a waterproof layer to prevent water from entering the inner cabinet body 1 through the at least one heat dissipation window 130. The technical details of the inner cabinet body 1 and the outer cover 2 have been described in the first embodiment, and will not be reiterated herein.

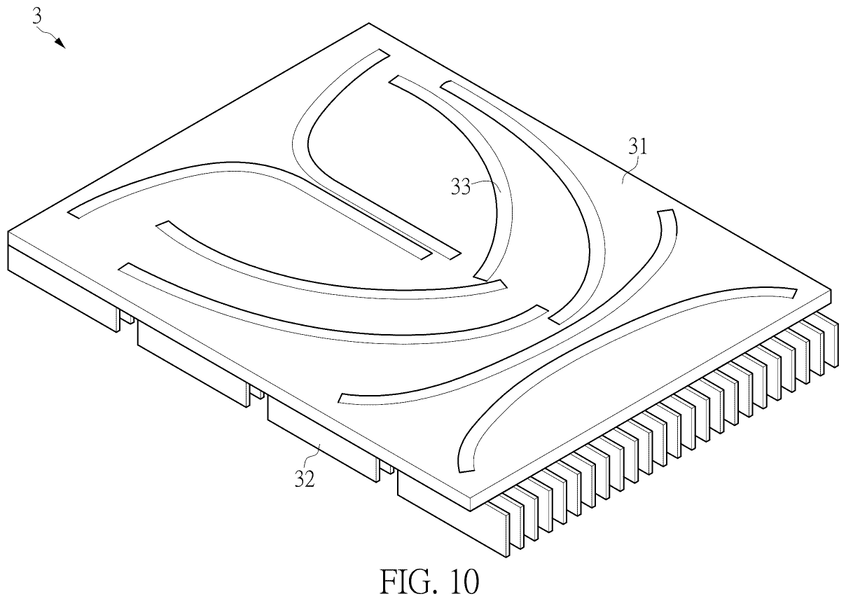

Reference is made to FIG. 10. The heat sink 3 includes a base 31 and a plurality of heat dissipation fins 32 connected to the base 31. More specifically, the base 31 is located in an accommodation space 100 of the inner cabinet body 1 to be in contact or exchange heat with a heat source. The heat dissipation fins 32 are located between the rear wall 13 of the inner cabinet body 1 and a rear baffle 22 of the outer cover 2 and connected to the base 31 through the heat dissipation window 130. Preferably, the heat dissipation fins 32 are adjacent to a plurality of heat dissipation holes 220 of the rear baffle 22. According to particular requirements, the base 31 can have a plurality of heat pipes 33 buried therein to reduce temperature differences between different positions of the base 31. For example, the base 31 can be made of aluminum, the heat dissipation fins 32 can be made of an aluminum alloy, and the heat pipes 33 can be made of copper. However, the present disclosure is not limited by said specific examples.

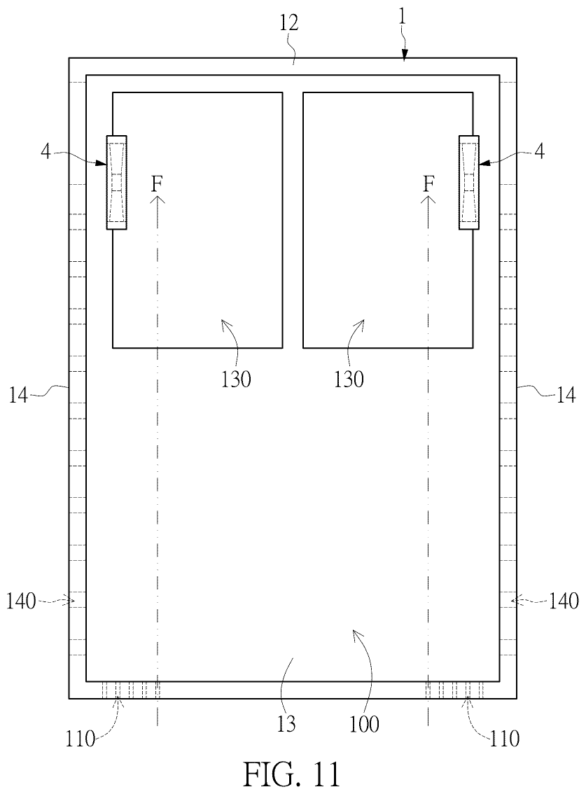

Reference is made to FIG. 11. The waterproof heat dissipation cabinet Z of the present embodiment can further include at least one airflow driver 4, which is disposed in the accommodation space 100 of the inner cabinet body 1, and is configured to produce a forced airflow from a plurality of first ventilation holes 110 to the at least one heat dissipation window 130, thereby fully utilizing natural air for heat dissipation. Therefore, heat accumulated in the inner cabinet body 1 can be promptly dissipated. The at least one airflow driver 4 can be at least one cooling fan that is installed at a position corresponding to the at least one heat dissipation window 130, but the present disclosure is not limited thereto.

In practice, the rear wall 13 of the inner cabinet body 1 can have two heat dissipation windows 130 in a side-by-side arrangement. One of the two heat dissipation windows 130 corresponds in position to a ventilation hole array A on a bottom wall 11 in an up-down direction, and the other of the two heat dissipation windows 130 corresponds in position to a ventilation hole array B on the bottom wall 11 in an up-down direction. Furthermore, two heat sinks 3 can be provided and respectively pass through the two heat dissipation windows 130. Two airflow drivers 4 can be provided and correspond in position to the heat sinks 3 in a front-rear direction. However, the above description is disclosed for exemplary purposes only, and is not meant to limit the scope of the present disclosure.

### Beneficial Effects of the Embodiments

In conclusion, by virtue of the inner cabinet body including a bottom wall having a plurality of first ventilation holes, a rear wall having at least one heat dissipation window, and two side walls each having a plurality of second ventilation holes, and the outer cover including two side baffles each blocking a plurality of second ventilation holes of the corresponding side wall and a rear baffle having a plurality of heat dissipation holes that provide for air communication between the at least one heat dissipation window of the rear wall and the external environment, the waterproof heat dissipation cabinet provided by the present disclosure can not only achieve a high waterproof grade that is ideal for long-term outdoor use, but also meet the heat dissipation requirements of high-power electronic components.

More specifically, the waterproof heat dissipation cabinet provided by the present disclosure can fully utilize natural air for heat dissipation and prevent rainwater from entering the inner cabinet body through hollow structures (e.g., holes, openings, or gaps), thereby being highly practical in the field of outdoor cabinets. After testing, the waterproof heat dissipation cabinet provided by the present disclosure can reach the waterproof grade of IPX6.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A waterproof heat dissipation cabinet, comprising:
an inner cabinet body including a bottom wall, a top wall, a rear wall, and two side walls that jointly define an accommodation space, wherein the bottom wall has a plurality of first ventilation holes, the rear wall has at least one heat dissipation window, and each of the two side walls has a plurality of second ventilation holes; and
an outer cover housing the inner cabinet body and including a top baffle, a rear baffle, and two side baffles, the top baffle corresponding in position to the top wall, the rear baffle corresponding in position to the rear wall, the two side baffles respectively corresponding in position to the two side walls, and each of the two side baffles shielding the second ventilation holes of the corresponding side wall; wherein the rear baffle has a plurality of heat dissipation holes that provide for air communication between the at least one heat dissipation window and an external environment.

2. The waterproof heat dissipation cabinet according to claim 1, wherein each of the two side walls and the corresponding side baffle have a plurality of shielding portions disposed therebetween to respectively shield the second ventilation holes, and each of the shielding portions has an opening that provides for air communication between the shielded second ventilation hole and the external environment.

3. The waterproof heat dissipation cabinet according to claim 2, wherein each of the shielding portions has a water shielding panel that extends from an external wall surface of the corresponding side wall to shield the corresponding second ventilation hole, and the water shielding panel has a curved guiding surface.

4. The waterproof heat dissipation cabinet according to claim 1, wherein the rear baffle and each of the two side baffles have a heat dissipation gap therebetween, and the rear baffle and the top baffle have another heat dissipation gap therebetween.

5. The waterproof heat dissipation cabinet according to claim 1, wherein the bottom wall has a central area and first and second peripheral areas located at two opposite sides of the central area, the first ventilation holes are arranged on the bottom wall into two ventilation hole arrays, one of the two ventilation hole arrays is located in the first peripheral area, and another of the two ventilation hole arrays is located in the second peripheral area; wherein the second ventilation holes are arranged side-by-side in pairs on each of the two side walls.

6. The waterproof heat dissipation cabinet according to claim 1, further comprising at least one heat sink that is disposed on the rear wall of the inner cabinet body.

7. The waterproof heat dissipation cabinet according to claim 6, wherein the at least one heat sink passes through the at least one heat dissipation window.

8. The waterproof heat dissipation cabinet according to claim 7, wherein the at least one heat sink includes a base and a plurality of heat dissipation fins, the base is located in the accommodation space of the inner cabinet body, and the heat dissipation fins are located between the rear wall of the inner cabinet body and the rear baffle of the outer cover and connected to the base through the at least one heat dissipation window.

9. The waterproof heat dissipation cabinet according to claim 8, wherein the heat dissipation fins are adjacent to the heat dissipation holes.

10. The waterproof heat dissipation cabinet according to claim 8, wherein the base has a plurality of heat pipes buried therein.
